(19) United States
(12) Patent Application Publication
(10) Pub. No.: US 2023/0010284 A1
(43) Pub. Date: Jan. 12, 2023

(54) MEASUREMENT APPARATUS, MEASUREMENT COMPENSATION SYSTEM, MEASUREMENT METHOD AND MEASUREMENT COMPENSATION METHOD

(71) Applicant: CHANGXIN MEMORY TECHNOLOGIES, INC., Hefei City (CN)

(72) Inventor: Xiang LI, Hefei (CN)

(21) Appl. No.: 17/669,571

(22) Filed: Feb. 11, 2022

Related U.S. Application Data
(63) Continuation of application No. PCT/CN2021/117061, filed on Sep. 8, 2021.

(30) Foreign Application Priority Data
Jul. 7, 2021 (CN) 202110769250.1

(51) Int. Cl. G01S 17/88; H01L 21/68; G01S 17/08; G01S 17/86

(52) U.S. Cl. CPC G01S 17/88; H01L 21/681; G01S 17/08; G01S 17/86; H01J 37/32715

(57) ABSTRACT

A measurement apparatus, a measurement compensation system, a measurement method and a measurement compensation method are provided. The measurement apparatus includes a jig wafer including: a wafer; a distance measuring sensor disposed on a front surface of the wafer and configured to measure a distance between the jig wafer and an upper electrode on the top of a reaction chamber after the jig wafer is placed on a wafer chuck of the reaction chamber; a horizontal sensor disposed on the front surface of the wafer and configured to measure the horizontal condition of the wafer chuck after the jig wafer is placed on the wafer chuck; and a data transmitting device connected with the distance measuring sensor and the horizontal sensor and configured to transmit the data measured by the distance measuring sensor and the data measured by the horizontal sensor.

### CROSS-REFERENCE TO RELATED APPLICATION

This application is a continuation application of International Patent Application No. PCT/CN2021/117061, filed on Sep. 8, 2021, which claims the priority of Chinese Patent Application No. 202110769250.1, filed to the China National Intellectual Property Administration on Jul. 7, 2021, and entitled “Measurement apparatus, Measurement Compensation System, Measurement Method and Measurement Compensation Method”. The entire contents of International Patent Application No. PCT/CN2021/117061 and Chinese Patent Application No. 202110769250.1 are incorporated herein by reference.

### BACKGROUND

With the rapid development of the science and technology, electronic products such as smart phones and tablet computers have become indispensable products in modern life. There are many semiconductor chips inside these electronic products, and the main manufacturing material of a semiconductor chip is a wafer. The wafer needs to be etched to form a line pattern, and semiconductor equipment is usually used to etch the wafer. Taking an etching machine as an example, the etching machine may include a reaction chamber body, an upper electrode and a wafer chuck, the reaction chamber body is provided with a reaction chamber, the upper electrode and the wafer chuck are located in the reaction chamber, a wafer is placed on the wafer chuck, and the lower electrode applies adsorption voltage to the wafer chuck so as to adsorb the wafer to the wafer chuck.

According to the requirements of the etching process, the distance between the wafer chuck and the upper electrode is accurately controlled to reach an optimal discharge position, so as to better achieve the accuracy of the process. Furthermore, when the etching machine works, the inside of the reaction chamber is a plasma environment, and at this time, the wafer is easily ionized to make the wafer negatively charged, which easily causes the voltage difference between a positive electrode region and a negative electrode region of the wafer chuck and the wafer to be unequal, so that the wafer chuck is deflected, resulting in lower safety and reliability of the etching machine. Therefore, in the etching process, the horizontal of the wafer chuck also needs to be accurately controlled. At present, in the etching process, a calibration jig and a vernier caliper are usually used manually to measure the distance between the wafer chuck and the upper electrode, and the process substantially includes: the calibration jig is placed in the reaction chamber, the reaction chamber is closed and then opened, the calibration jig is taken out, and then, the vernier caliper is used to measure the length of the calibration jig.

However, manual measurement inevitably has errors and faults, so that the accuracy is lower. Moreover, since manual measurement requires multiple opening and closing of the reaction chamber, the machine needs to be restarted after the measurement is completed, which increases the downtime of the machine table and causes lower work efficiency.

### SUMMARY

This disclosure relates to the field of the semiconductor technology, and particularly relates to a measurement apparatus, a measurement compensation system, a measurement method and a measurement compensation method.

This disclosure provides a measurement apparatus. The measurement apparatus includes a jig wafer. The jig wafer includes:

a wafer;

a distance measuring sensor disposed on a front surface of the wafer and configured to measure the distance between the jig wafer and an upper electrode on the top of a reaction chamber after the jig wafer is placed on a wafer chuck of the reaction chamber;

a horizontal sensor disposed on the front surface of the wafer and configured to measure the horizontal condition of the wafer chuck after the jig wafer is placed on the wafer chuck; and

a data transmitting device connected with the distance measuring sensor and the horizontal sensor and configured to transmit the data measured by the distance measuring sensor and the data measured by the horizontal sensor.

This disclosure further provides a measurement compensation system, including:

the measurement apparatus as described in the above embodiment; and

a compensation system connected with the data transmitting module and a machine table where the reaction chamber is located, and configured to compensate the machine table according to the distance compensation value and/or the horizontal compensation value.

This disclosure further provides a measurement method, including the following operations.

The measurement apparatus as described in the above embodiment is provided, and the jig wafer is conveyed onto the wafer chuck.

The distance between the jig wafer and the upper electrode on the top of the reaction chamber is measured by using the distance measuring sensor.

The horizontal condition of the wafer chuck is measured by using the horizontal sensor.

This disclosure further provides a measurement compensation method, including the following operations.

The distance compensation value and/or the horizontal compensation value are/is obtained by using the measurement method as described in the above embodiment.

The machine table where the reaction chamber is located is compensated according to the distance compensation value and/or the horizontal compensation value.

### BRIEF DESCRIPTION OF THE DRAWINGS

In order to illustrate the technical solutions of the embodiments of this disclosure or the traditional technology more clearly, the following will briefly introduce the accompanying drawings required for describing the embodiments or the traditional technology. Apparently, the accompanying drawings in the following description illustrate only some embodiments of this disclosure, and a person of ordinary skill in the art may still derive other accompanying drawings from these accompanying drawings without creative efforts.

FIG. 1 is a schematic structural diagram of a measurement apparatus provided in an embodiment of this disclosure.

FIG. 2 is a schematic diagram of measurement performed by a measurement apparatus provided in another embodiment of this disclosure.

FIG. 3 is a top view diagram of a jig wafer in a measurement apparatus provided in an embodiment of this disclosure.

FIG. 4 is a top view diagram of a jig wafer illustrating only a wafer and distance measuring sensors in a measurement apparatus provided in another embodiment of this disclosure.

FIG. 5 is a flowchart of a measurement method provided in an embodiment of this disclosure.

FIG. 6 is a flowchart of a measurement compensation method provided in an embodiment of this disclosure.

### DETAILED DESCRIPTION

For convenience of an understanding of this disclosure, this disclosure will now be described more fully below with reference to the related accompanying drawings. A preferred embodiment of this disclosure is illustrated in the accompanying diagrams. This disclosure may, however, be embodied in many different forms which are not limited to the embodiments described herein. Rather, these embodiments provided are intend to make the disclosed content of this disclosure more thorough and complete.

Unless defined otherwise, all technical and scientific terms used herein have the same meanings as commonly understood by those skilled in the art to which this disclosure belongs. The terms used herein in the specification of this disclosure is for the purpose of describing specific embodiments only and is not intended to limit this disclosure.

It should be understood that when an element or a layer is referred to as being “on” or “connected with” other elements, the element or the layer may be directly located on other elements or connected with other elements, or there may be an intermediate element.

The embodiments of the disclosure are described here with reference to a plane top view serving as an ideal embodiment (and an intermediate structure) of this disclosure, so that the change in the illustrated shape due to a manufacturing technology and/or a tolerance can be expected. Therefore, the embodiments of this disclosure should not be limited to the particular shapes of regions illustrated herein, but include shape variations due to, for example, manufacturing technologies. Therefore, the regions illustrated in the figures are schematic substantially and their shapes do not represent actual shapes of the regions of the devices and do not limit the scope of this application.

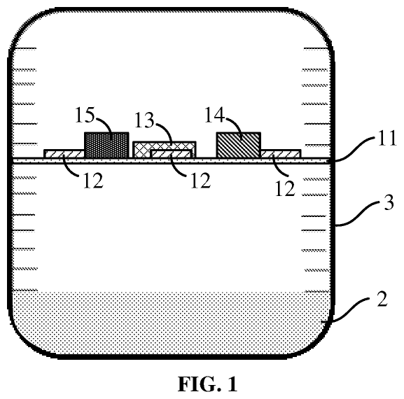

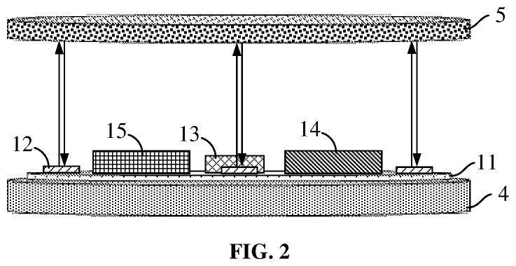

Referring to FIG. 1 to FIG. 2, this disclosure provides a measurement apparatus. The measurement apparatus includes a jig wafer. The jig wafer includes a wafer 11, distance measuring sensors 12, a horizontal sensor 13 and a data transmitting device 14. The distance measuring sensors 12 are disposed on a front surface of the wafer 11 and configured to measure the distance between the jig wafer and an upper electrode 5 on the top of a reaction chamber after the jig wafer is placed on a wafer chuck 4 of the reaction chamber. The horizontal sensor 13 are disposed on the front surface of the wafer 11 and configured to measure the horizontal condition of the wafer chuck 4 after the jig wafer is placed on the wafer chuck 4. The data transmitting device 14 is connected with the distance measuring sensors 12 and the horizontal sensor 13 and configured to transmit the data measured by the distance measuring sensors 12 and the data measured by the horizontal sensors 13.

According to the measurement apparatus in this disclosure, by disposing the distance measuring sensors 12 on the front surface of the wafer 11, there is no need to open the reaction chamber and manually use a calibration jig and a vernier caliper to measure the distance between the wafer chuck 4 and the upper electrode 5, so that the error caused by manual measurement is avoided, and the accuracy is higher. Furthermore, after the measurement is completed, there is no need to restart the machine, so that the downtime of the machine table can be shortened to improve the work efficiency. Further, according to the measurement apparatus in this disclosure, by disposing the horizontal sensor 13 on the front surface of the wafer 11, the horizontal condition of the wafer chuck 4 can be obtained in real time without opening the reaction chamber. When the wafer chuck 4 is deflected, the deflected wafer chuck 4 can be found in time to prevent the detection anomaly caused by the deflection of the horizontal position of the wafer chuck, and the working safety and reliability of the reaction chamber can be improved.

Continuing to refer to FIG. 1 to FIG. 2, in one of the embodiments, the number of the distance measuring sensors 12 may be multiple, such as 1, 3, or 5. This disclosure does not limit the number of the distance measuring sensors 12. Multiple distance measuring sensors 12 may be arranged at intervals on the front surface of the wafer 11.

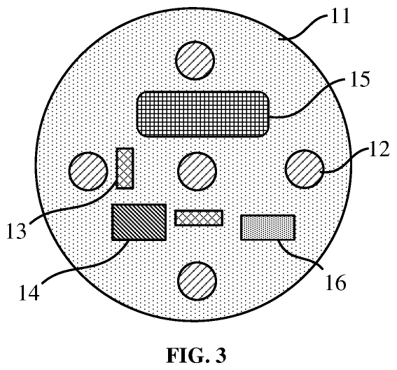

Specifically, referring to FIG. 3, in one of the embodiments, five distance measuring sensors 12 may be disposed on the front surface of the wafer 11 as an example.

Continuing to refer to FIG. 3, in one of the embodiments, one of the distance measuring sensors 12 may be located at the center of the wafer 11, and the other distance measuring sensors 12 may be distributed symmetrically with the center of the wafer 11 as a center point. In other embodiments, the arrangement mode of the multiple distance measuring sensors 12 may also be adaptively adjusted by workers according to actual situations. This disclosure does not limit the specific arrangement mode of the multiple distance measuring sensors 12.

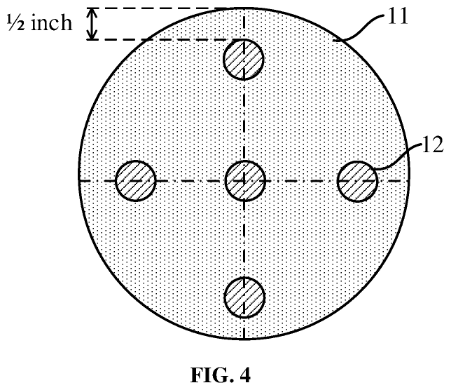

Referring to FIG. 4, in one of the embodiments, if the size of the wafer 11 is 300 mm, the distance between the distance measuring sensors 12 which are distributed symmetrically with the center of the wafer 11 as the center point and the edge of the wafer 11 may be 0.4-0.8 inch, such as 0.4, 0.5, 0.6, 0.7 or 0.8 inch. This disclosure does not limit the distance between the distance measuring sensors 12 which are distributed symmetrically with the center of the wafer 11 as the center point and the edge of the wafer 11. Specifically, in one of the embodiments, the distance between the distance measuring sensors 12 which are distributed symmetrically with the center of the wafer 11 as the center point and the edge of the wafer 11 is 0.5 inch.

It should be noted that the above data only serves as an example. In an actual embodiment, the distance between the distance measuring sensors 12 which are distributed symmetrically with the center of the wafer 11 as the center point and the edge of the wafer 11 is not limited by the above data.

The distance measuring sensor 12 may include, but are not limited to, any one or more of infrared distance measuring sensor, ultrasonic distance measuring sensor, laser distance measuring sensor, radar sensor, etc. This disclosure does not limit the type of the distance measuring sensor 12. Specifically, in one of the embodiments, the distance measuring sensor 12 include infrared distance measuring sensor.

In one of the embodiments, an infrared distance measuring sensor may have a pair of infrared signal emitting diode and infrared signal receiving diode and a signal processor. As illustrated in FIG. 2, the infrared distance measuring sensor can use the infrared signal emitting diode to emit a beam of infrared signal which irradiates the upper electrode 5 to form a reflection process, the infrared signal receiving diode receives the infrared signal and processes the data of the time difference between emission and reception, and the signal processor processes the data of the time difference to obtain the distance between the jig wafer and the upper electrode 5.

The measurement apparatus provided in the above embodiment can avoid difficult operations and errors caused by the auxiliary reflection of a reflector plate required for the reflection of the infrared signal, thereby improving the accuracy of measuring the distance between the jig wafer and the upper electrode 5.

Continuing to refer to FIG. 3, in one of the embodiments, the number of the horizontal sensors 13 may be multiple, such as 1, 2, 3, or 4. This disclosure does not limit the number of the horizontal sensors 13. Multiple horizontal sensors 13 may be arranged at intervals on the front surface of the wafer 11.

The horizontal sensor 13 may include, but are not limited to, dual-axis horizontal sensor or other horizontal sensor. This disclosure does not limit the type of the horizontal sensor 13. Specifically, in one of the embodiments, the horizontal sensor 13 includes dual-axis horizontal sensor. The dual-axis horizontal sensor can simultaneously measure the horizontal angles in two directions (that is, a pitch angle and a roll angle), and can convert the inclination angle signals of the horizontal angles in the two directions into usable output electrical signals according to certain rules, so that the horizontal degree of the entire measured surface can be determined.

The data transmitting device 14 may include, but is not limited to, a Wi-Fi transmitting module, a Bluetooth transmitting module, an infrared transmitting module, a Near Field Communication (NFC) transmitting module, a ZigBee transmitting module, etc. This disclosure does not limit the type of the data transmitting device 14. Specifically, in one of the embodiments, the data transmitting device 14 includes a Wi-Fi transmitting module.

Continuing to refer to FIG. 1 to FIG. 3, in one of the embodiments, the jig wafer further includes a control circuit 15. The control circuit 15 is located on the wafer 11. The data transmitting device 14 is connected with the distance measuring sensors 12 and the horizontal sensors 13 through the control circuit 15. The control circuit 15 is configured to control the distance measuring sensors 12, the horizontal sensors 13 and the data transmitting device 14 to work, collect the data measured by the distance measuring sensors 12 and the horizontal sensors 13, and send the data to the data transmitting device 14.

Continuing to refer to FIG. 3, in one of the embodiments, the jig wafer may further include a switch 16. The switch 16 is located on the wafer 11, connected with the control circuit 15, and configured to control the turning-on and turning-off of the control circuit 15.

Continuing to refer to FIG. 1, in one of the embodiments, the measurement apparatus may further include a communication device 2 and a data processing device (not illustrated in the figure), and the communication device 2 includes a data receiving module and a data transmitting module.

Specifically, the data receiving module is in communication connection with the data transmitting device 14 and is configured to receive the data measured by the distance measuring sensors 12 and the data measured by the horizontal sensors 13, which are transmitted by the data transmitting device 14. The data processing device is connected with the data receiving module and the data transmitting module, and is configured to analyze the data measured by the distance measuring sensors 12 and the data measured by the horizontal sensors 13, so as to determine whether the distance between the jig wafer and the upper electrode 5 has a distance deviation and whether the wafer chuck 4 has a horizontal deviation, and obtain a distance compensation value according to the data measured by the distance measuring sensors 12 in case that there exists the distance deviation as well as obtain a horizontal compensation value according to the data measured by the horizontal sensors 13 in case that there exists the horizontal deviation; and the data transmitting module is configured to transmit the distance compensation value and the horizontal compensation value.

Continuing to refer to FIG. 1, in one of the embodiments, the measurement apparatus may further include a jig Front Opening Unified Pod (FOUP) 3.

In one of the embodiments, the communication device 2 and/or the data processing device may be located inside the jig FOUP 3, and the communication device 2 and/or the data processing device may also be located outside the jig FOUP 3. This disclosure does not limit the specific placement positions of the communication device 2 and the data processing device.

This disclosure further provides a measurement compensation system, including the measurement apparatus as described in any one of the above embodiments and a compensation system. The compensation system is connected with the data transmitting module and a machine table where the reaction chamber is located, and is configured to compensate the machine table according to the distance compensation value and/or the horizontal compensation value.

Specifically, the machine table can use a mechanical arm to convey the jig wafer to the position that needs to be calibrated, and the data transmitting module can feed back the distance compensation value and/or the horizontal compensation value obtained by the data processing device to the machine table so as to compensate the machine table, thereby completing the calibration.

According to the measurement compensation system in this disclosure, by using the measurement apparatus to measure the distance between the wafer chuck 4 and the upper electrode 5 and obtaining the horizontal condition of the wafer chuck 4, there is no need to open the reaction chamber for manual measurement, so that the error caused by manual measurement is avoided, and the accuracy is higher. Furthermore, after the measurement is completed, there is no need to restart the machine, so that the downtime of the machine table can be shortened to improve the work efficiency. When the wafer chuck 4 is deflected, the deflected wafer chuck 4 can be found in time, so that the working safety and reliability of the reaction chamber can be improved. According to the measurement compensation system in this disclosure, by using the compensation system to compensate the machine table, the reaction chamber can better achieve the accuracy of the process in the subsequent etching process.

In one of the embodiments, the compensation system may include, but is not limited to, a machine table operating system.

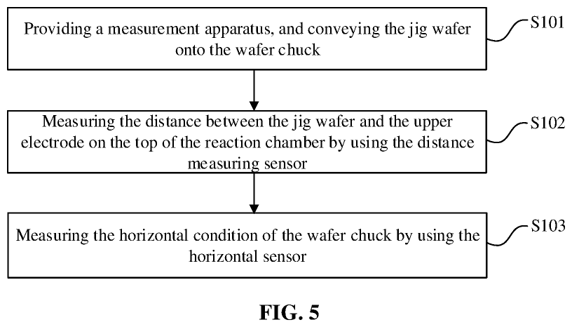

Referring to FIG. 5 in conjunction with FIG. 2, this disclosure further provides a measurement method, including the following operations:

in S101, the measurement apparatus as described in any one of the above embodiments is provided, and the jig wafer is conveyed onto the wafer chuck 4;

in S102, the distance between the jig wafer and the upper electrode 5 on the top of the reaction chamber is measured by using the distance measuring sensor 12; and

in S103, the horizontal condition of the wafer chuck 4 is measured by using the horizontal sensor 13.

According to the measurement method in this disclosure, by using the distance measuring sensor 12 disposed on the front surface of the wafer 11 to measure the distance between the wafer chuck 4 and the upper electrode 5, there is no need to open the reaction chamber and manually use the calibration jig and the vernier caliper to measure the distance between the wafer chuck 4 and the upper electrode 5, so that the error caused by manual measurement is avoided, and the accuracy is higher. Furthermore, after the measurement is completed, there is no need to restart the machine, so that the downtime of the machine table can be shortened to improve the work efficiency. Further, according to the measurement method in this disclosure, by disposing the horizontal sensor 13 on the front surface of the wafer 11, the horizontal condition of the wafer chuck 4 can be obtained in real time without opening the reaction chamber. When the wafer chuck 4 is deflected, the deflected wafer chuck can be found in time, so that the working safety and reliability of the reaction chamber can be improved.

Continuing to refer to FIG. 2, in one of the embodiments, the measurement method may also include the following operations:

whether the distance between the jig wafer and the upper electrode 5 has a distance deviation is determined based on the data measured by the distance measuring sensor 12, and a distance compensation value is obtained according to the data measured by the distance measuring sensor 12 in case that there exists the distance deviation.

In one of the embodiments, the measurement method may also include the following operations:

whether the wafer chuck 4 has a horizontal deviation is determined based on the data measured by the horizontal sensor 13, and a horizontal compensation value is obtained according to the data measured by the horizontal sensor 13 in case that there exists the horizontal deviation.

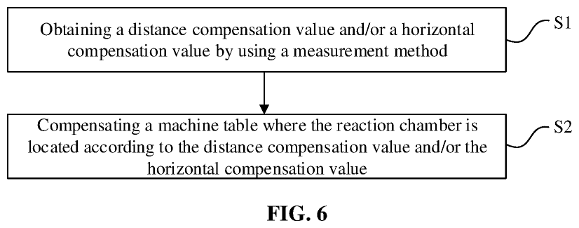

Referring to FIG. 6, this disclosure further provides a measurement compensation method, including the following operations:

in S1, the distance compensation value and/or the horizontal compensation value are/is obtained by using the measurement method as described in any one of the above embodiments; and

in S2, the machine table where the reaction chamber is located is compensated according to the distance compensation value and/or the horizontal compensation value.

According to the measurement compensation method in this disclosure, by using the compensation system to compensate the machine table, the reaction chamber can better achieve the accuracy of the process in the subsequent etching process.

In one of the embodiments, the machine table where the reaction chamber is located can be compensated according to the distance compensation value, the horizontal compensation value, or the distance compensation value and the horizontal compensation value by using the machine table operating system.

It should be understood that although various operations in the flow charts of FIG. 5 and FIG. 6 are displayed in sequence as indicated by arrows, these operations are not necessarily executed in sequence according to the order indicated by the arrows. Unless there is a clear description in the disclosure, there is no strict order limitation on the execution of these operations, and these operations may be executed in other orders. Furthermore, at least part of the operations in FIG. 5 to FIG. 6 may include multiple operations or multiple stages, these operations or stages are not necessarily executed at the same time, but may be executed at different times, and these operations or stages are not necessarily executed in sequence, but may be executed in turn or alternately with other operations or at least part of the operations or stages in other operations.

The technical features of the above embodiments may be combined arbitrarily. In order to simplify the description, all possible combinations of the technical features in the above embodiments are not completely described. However, as long as there is no conflict between these technical features, they should be considered to be within the scope of this specification.

The above embodiments represent only a few implementations of this application, and the descriptions are specific and detailed, but should not be construed as limiting the patent scope of this application. It should be noted that those of ordinary skill in the art may further make some variations and improvements without departing from the conception of this application, and these variations and improvements all fall within the protection scope of this application. Therefore, the patent protection scope of this application should be subject to the appended claims.

1. A measurement apparatus, comprising a jig wafer, the jig wafer comprising:
a wafer;
a distance measuring sensor, disposed on a front surface of the wafer, and configured to measure a distance between the jig wafer and an upper electrode on a top of a reaction chamber after the jig wafer is placed on a wafer chuck of the reaction chamber;
a horizontal sensor, disposed on the front surface of the wafer, and configured to measure a horizontal condition of the wafer chuck after the jig wafer is placed on the wafer chuck; and
a data transmitting device, connected with the distance measuring sensor and the horizontal sensor, and configured to transmit a first data measured by the distance measuring sensor and a second data measured by the horizontal sensor.

2. The measurement apparatus of claim 1, wherein there are a plurality of distance measuring sensors, and the plurality of distance measuring sensors are arranged at intervals on the front surface of the wafer.

3. The measurement apparatus of claim 2, wherein one of the plurality of distance measuring sensors is located at a center of the wafer, and other distance measuring sensors are distributed symmetrically with the center of the wafer as a center point.

4. The measurement apparatus of claim 1, wherein the distance measuring sensor comprise infrared distance measuring sensor.

5. The measurement apparatus of claim 1, wherein there are a plurality of horizontal sensors, and the plurality of horizontal sensors are arranged at intervals on the front surface of the wafer.

6. The measurement apparatus of claim 1, wherein the horizontal sensor comprises dual-axis horizontal sensor.

7. The measurement apparatus of claim 1, wherein the jig wafer further comprises:
a control circuit, located on the wafer; the data transmitting device being connected with the distance measuring sensor and the horizontal sensor through the control circuit; and the control circuit being configured to control the distance measuring sensor, the horizontal sensor and the data transmitting device to work, and to collect the first data measured by the distance measuring sensor and the second data measured by the horizontal sensor and send the first data and the second data to the data transmitting device.

8. The measurement apparatus of claim 7, wherein the jig wafer further comprises:
a switch, located on the wafer and connected with the control circuit, and configured to control a turning-on and a turning-off of the control circuit.

9. The measurement apparatus of claim 1, further comprising:
a communication device, comprising a data receiving module and a data transmitting module, the data receiving module being in a communication connection with the data transmitting device and being configured to receive the first data measured by the distance measuring sensor and the second data measured by the horizontal sensor, which are transmitted by the data transmitting device;
a data processing device, connected with the data receiving module and the data transmitting module; and configured to analyze the first data measured by the distance measuring sensor and the second data measured by the horizontal sensor to determine whether the distance between the jig wafer and the upper electrode has a distance deviation and to determine whether the wafer chuck has a horizontal deviation, and to obtain a distance compensation value according to the first data measured by the distance measuring sensor in case that there exists the distance deviation, and obtain a horizontal compensation value according to the second data measured by the horizontal sensor in case that there exists the horizontal deviation; and
the data transmitting module, configured to transmit the distance compensation value and the horizontal compensation value.

10. The measurement apparatus of claim 9, further comprising a jig FOUP, wherein the communication device and the data processing device are both located in the jig FOUP.

11. A measurement compensation system, comprising:
the measurement apparatus of claim 9; and
a compensation system, connected with the data transmitting module and a machine table where the reaction chamber is located, and configured to compensate the machine table according to at least one of the distance compensation value or the horizontal compensation value.

12. The measurement compensation system of claim 11, wherein the compensation system comprises a machine table operating system.

13. A measurement method, comprising:
providing the measurement apparatus of claim 1, and conveying the jig wafer onto the wafer chuck;
measuring the distance between the jig wafer and the upper electrode on the top of the reaction chamber by using the distance measuring sensor; and
measuring the horizontal condition of the wafer chuck by using the horizontal sensor.

14. The measurement method of claim 13, further comprising:
determining whether the distance between the jig wafer and the upper electrode has a distance deviation based on the first data measured by the distance measuring sensor, and obtaining a distance compensation value according to the first data measured by the distance measuring sensor in case that there exists the distance deviation; and
determining whether the wafer chuck has a horizontal deviation based on the second data measured by the horizontal sensor, and obtaining a horizontal compensation value according to the second data measured by the horizontal sensor in case that there exists the horizontal deviation.

15. A measurement compensation method, comprising:
obtaining at least one of the distance compensation value or the horizontal compensation value by using the measurement method of claim 14; and
compensating a machine table where the reaction chamber is located according to the at least one of the distance compensation value the horizontal compensation value.

16. The measurement compensation method of claim 15, wherein compensating a machine table where the reaction chamber is located according to the at least one of the distance compensation value the horizontal compensation value comprises:
compensating the machine table where the reaction chamber is located according to the at least one of the distance compensation value or the horizontal compensation value by using a machine table operating system.
